(19) United States
(12) Patent Application Publication
(10) Pub. No.: US 2012/0243317 A1
(43) Pub. Date: Sep. 27, 2012

(54) NON-VOLATILE SEMICONDUCTOR MEMORY DEVICE

(75) Inventors: Satoshi INOUE, Kanagawa (JP); Yuya Suzuki, Kanagawa (JP)

(73) Assignee: Kabushiki Kaisha Toshiba, Tokyo (JP)

(21) Appl. No.: 13/422,051

(22) Filed: Mar. 16, 2012

(30) Foreign Application Priority Data
Mar. 25, 2011 (JP) 2011-067467

(51) Int. Cl. G11C 16/10; G11C 16/04

(52) U.S. Cl. 365/185.17; 365/185.22

(57) ABSTRACT

According to one embodiment, a non-volatile semiconductor memory device includes a writing unit that performs a writing operation on memory cells while stepping up a writing voltage based on a check result of a verifying operation on the memory cells, a threshold-value determining unit that determines threshold values of the memory cells based on a write verifying operation on the memory cells, and a step-up voltage changing unit that changes a step-up voltage for stepping up the writing voltage, based on the threshold values of the memory cells.

### CROSS-REFERENCE TO RELATED APPLICATIONS

This application is based upon and claims the benefit of priority from Japanese Patent Application No. 2011-067467, filed on Mar. 25, 2011; the entire contents of which are incorporated herein by reference.

### FIELD

Embodiments described herein relate generally to a non-volatile semiconductor memory device.

### BACKGROUND

In a NAND-type flash memory, if a write cycle is repeated, cells are deteriorated such that a threshold value distribution widens. For this reason, the upper limit of the number of times of writing is determined.

Particularly, in a multi-leveled memory that stores two or more bits in one memory cell, since it is required to finely control a threshold value distribution, a step-wise writing voltage scheme may be used. In this step-wise writing voltage scheme, a writing voltage VPGM is stepped up by a constant step voltage value ΔVPGM for each write cycle.

As the step voltage value ΔVPGM decreases, a variation in the threshold values of the cells in one writing operation decreases. Therefore, it is possible to narrow the threshold value distribution. Therefore, in order to secure the reliability of data, it is desired to reduce the step voltage value ΔVPGM. However, in order to reduce the step voltage value ΔVPGM, it is required to repeatedly apply the writing voltage, and thus the writing time lengthens.

### BRIEF DESCRIPTION OF THE DRAWINGS

FIG. 1 is a block diagram illustrating a schematic configuration of a non-volatile semiconductor memory device according to a first embodiment;

FIG. 2 is a circuit diagram illustrating a schematic configuration of a block of the non-volatile semiconductor memory device of FIG. 1;

FIG. 3 is a cross-sectional view illustrating one cell unit of the non-volatile semiconductor memory device of FIG. 1;

FIG. 4 is a diagram illustrating a relation between the number of times of erasing and a step-up voltage in the non-volatile semiconductor memory device of FIG. 1;

FIG. 5 is a flow chart illustrating a write verifying operation of the non-volatile semiconductor memory device of FIG. 1;

FIG. 6 is a flow chart illustrating the writing process of FIG. 5;

FIG. 7 is a block diagram illustrating a schematic configuration of a non-volatile semiconductor memory device according to a second embodiment;

FIG. 8 is a diagram illustrating threshold voltage distributions of memory cells of the non-volatile semiconductor memory device of FIG. 7 during erasing and writing;

FIG. 9 is a flow chart illustrating a write verifying operation of the non-volatile semiconductor memory device of FIG. 7; and

FIG. 10 is a flow chart illustrating a write verifying operation of a non-volatile semiconductor memory device according to a third embodiment.

### DETAILED DESCRIPTION

A non-volatile semiconductor memory device according to an embodiment includes a memory cell array, a write verifying unit, a writing unit, a threshold-value determining unit, and a step-up voltage changing unit. The memory cell array includes a plurality of memory cells for each block. The write verifying unit performs a verifying operation with a plurality of verification levels during a writing operation on the memory cells. The writing unit performs a writing operation on the memory cells while stepping up the writing voltage based on a check result of the verifying operation. The threshold-value determining unit determines the threshold values of the memory cells based on a write verifying operation on the memory cells. The step-up voltage changing unit changes a step-up voltage for stepping up the writing voltage, based on the threshold values of the memory cells.

Hereinafter, non-volatile semiconductor memory devices according to embodiments will be described with reference to the drawings. However, the present invention is not limited to the embodiments.

### First Embodiment

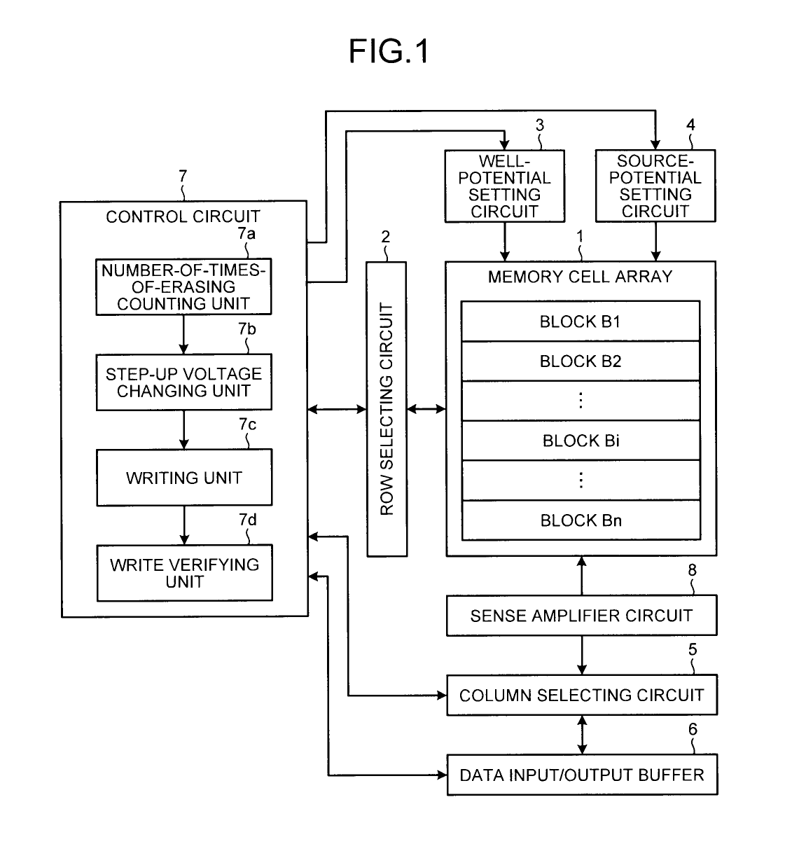

FIG. 1 is a block diagram illustrating a schematic configuration of a non-volatile semiconductor memory device according to a first embodiment.

In FIG. 1, the non-volatile semiconductor memory device includes a memory cell array 1, a row selecting circuit 2, a well-potential setting circuit 3, a source-potential setting circuit 4, a column selecting circuit 5, a data input/output buffer 6, a control circuit 7, and a sense amplifier circuit 8.

The memory cell array 1 includes memory cells which store data and are disposed in a matrix in a row direction and a column direction. Each memory cell may be configured to store 1-bit data or may be multi-leveled to be capable of storing two or more bits of data.

Here, the memory cell array 1 is divided into n-number of blocks B1 to Bn (n is a positive integer). Each of the blocks B1 to Bn can be configured by disposing a plurality of NAND cell units in the row direction.

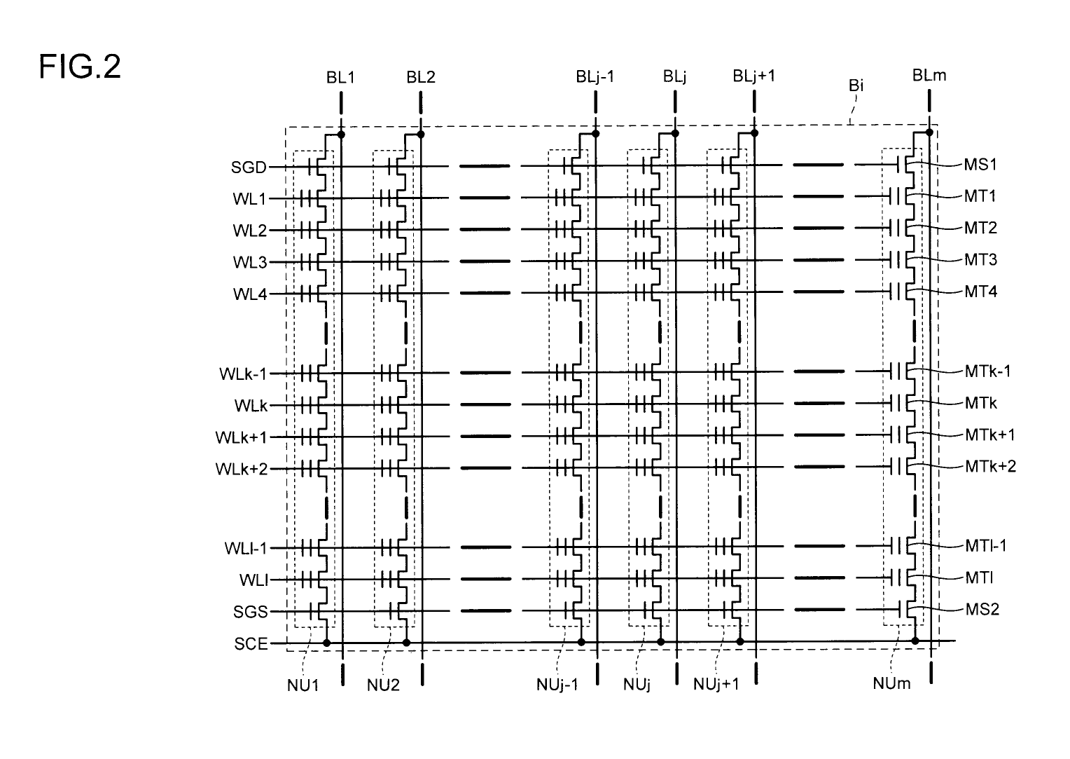

FIG. 2 is a circuit diagram illustrating a schematic configuration of a block of the non-volatile semiconductor memory device of FIG. 1.

In FIG. 2, the block Bi (i is an integer satisfying 1≦i≦n) includes 1-number of word lines WL1 to WL1 (1 is a positive integer), selection gate lines SGD and SGS, and a source line SCE. In the blocks B1 to Bn, m-number of common bit lines BL1 to BLm (m is a positive integer) are provided.

The block Bi includes m-number of NAND cell units NU1 to NUm, and the NAND cell units NU1 to NUm are connected to the bit lines BL1 to BLm, respectively.

Here, each of the NAND cell units NU1 to NUm includes cell transistors MT1 to MT1, and selection transistors MS1 and MS2. Each memory cell of the memory cell array 1 can be composed of one cell transistor MTk (here, k is an integer satisfying 1≦k≦1). The cell transistors MT1 to MT1 are connected in series, so as to form a NAND string, and both ends of the NAND string are connected to the selection transistors MS1 and MS2, whereby a NAND cell unit NUj (here, j is an integer satisfying 1≦j≦m) is formed.

In the NAND cell units NU1 to NUm, control gate electrodes of the cell transistors MT1 to MT1 are connected to the word lines WL1 to WL1, respectively. Further, in the NAND cell unit NUj, one end of the NAND string composed of the cell transistors MT1 to MT1 is connected to a bit line BLj through the selection transistor MS1, and the other end of the NAND string is connected to the source line SCE trough the selection transistor MS2. Furthermore, gate electrodes of the selection transistors MS1 and MS2 are connected to the selection gate lines SGD and SGS, respectively.

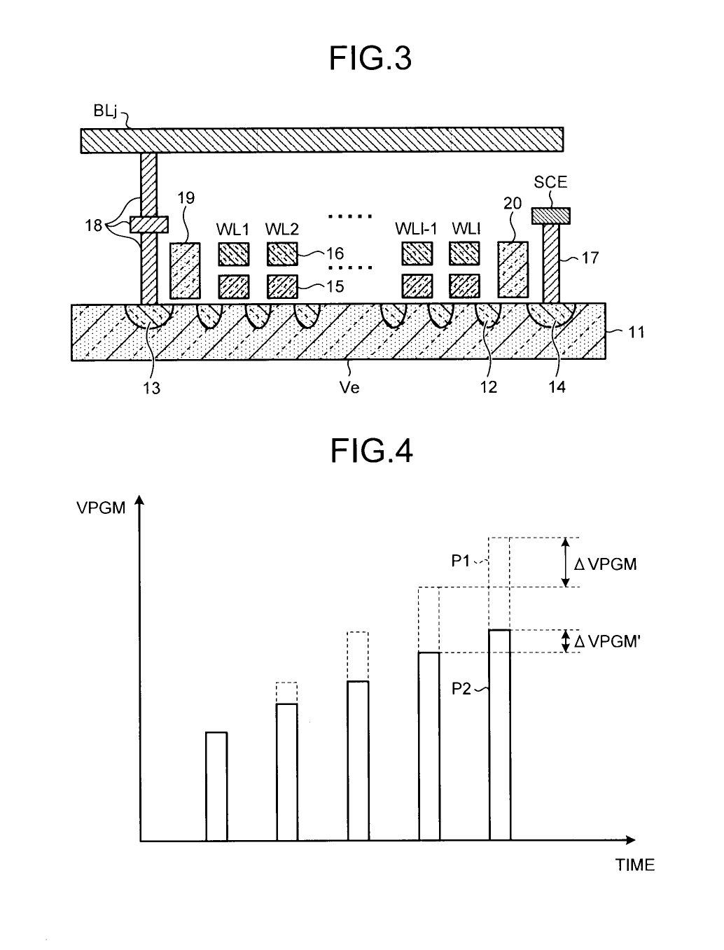

FIG. 3 is a cross-sectional view corresponding to one cell unit of the non-volatile semiconductor memory device of FIG. 1.

In FIG. 3, floating gate electrodes 15 and selection gate electrodes 19 and 20 are disposed on a well 11. On the floating gate electrodes 15, control gate electrodes 16 are disposed. The well 11 and the floating gate electrodes 15 can be insulated from each other by a tunnel insulator film (not illustrated). The floating gate electrodes 15 and the control gate electrodes 16 can be insulated from each other by an inter-electrode insulator film (not illustrated). Here, one memory cell can be composed of one floating gate electrode 15 and a control gate electrode 16 formed on the corresponding floating gate electrode 15.

Also, in the well 11, impurity diffused layers 12, 13, and 14 are formed between the floating gate electrodes 15 or between a floating gate electrode 15 and the selection gate electrode 19 or 20. For example, the well 11 can be a P type, and the impurity diffused layers 12, 13, and 14 can be an N type.

The impurity diffused layer 13 is connected to the bit line BLj through a connection conductor 18, and the impurity diffused layer 14 is connected to the source line SCE through a connection conductor 17. Further, the control gate electrodes 16 of the individual memory cells are connected to the word lines WL1 to WL1, and the selection gate electrodes 19 and 20 are connected to the selection gate lines SGD and SGS, respectively.

In FIG. 1, the row selecting circuit 2 can select memory cells in the row direction of the memory cell array 1 during reading, writing, or erasing on the memory cells. The well-potential setting circuit 3 can set a well potential of the memory cell array 1 during the reading, writing, or erasing on memory cells. The source-potential setting circuit 4 can set a source potential of the memory cell array 1 during the reading, writing, or erasing on memory cells. The column selecting circuit 5 can select memory cells in the column direction of the memory cell array 1 during the reading, writing, or erasing on the memory cells. The sense amplifier circuit 8 can discriminate data output from the memory cells for each column. The data input/output buffer 6 can transmit a command and an address, received from the outside, to the control circuit 7, and perform data communication between the sense amplifier circuit 8 and the outside.

On the basis of the command and address, the control circuit 7 can control the operations of the row selecting circuit 2, the well-potential setting circuit 3, the source-potential setting circuit 4, and the column selecting circuit 5. Here, the control circuit 7 includes a number-of-times-of-erasing counting unit 7a, a step-up voltage changing unit 7b, a writing unit 7c, and a write verifying unit 7d.

The number-of-times-of-erasing counting unit 7a can count the number of times of erasing on the memory cells in units of the blocks B1 to Bn. The writing unit 7c can perform a writing operation on the memory cells. Also, the writing unit 7c can step up a writing voltage VPGM on the basis of a check result of a verifying operation. The write verifying unit 7d can perform a verifying operation during a writing operation on the memory cells. The step-up voltage changing unit 7b can change a step-up voltage ΔVPGM for stepping up the writing voltage VPGM, on the basis of the number of times of erasing on the memory cells. Specifically, if the number of times of erasing on the memory cells exceeds a specified value, the step-up voltage ΔVPGM can be reduced.

FIG. 4 is a diagram illustrating a relation between the number of times of erasing and the step-up voltage in the non-volatile semiconductor memory device of FIG. 1. Reference numeral P1 denotes a method of stepping up the writing voltage VPGM when the number of times of erasing on the memory cells is equal to or less than the specified value, and reference numeral P2 denotes a method of stepping up the writing voltage VPGM when the number of times of erasing on the memory cells is larger than the specified value.

In FIG. 4, in the case where the number of times of erasing on the memory cells is equal to or less than the specified value, the step-up voltage is set to ΔVPGM. Then, the writing voltage VPGM is repeatedly applied while increasing by the step-up voltage ΔVPGM, until a verification check is passed, whereby writing on the memory cells is performed.

Meanwhile, in the case where the number of times of erasing on the memory cells is larger than the specified value, the step-up voltage changes from ΔVPGM to ΔVPGM. Here, ΔVPGM′ is smaller than ΔVPGM. Then, the writing voltage VPGM is repeatedly applied while increasing by the step-up voltage ΔVPGM', until the verification check is passed, whereby writing on the memory cells is performed.

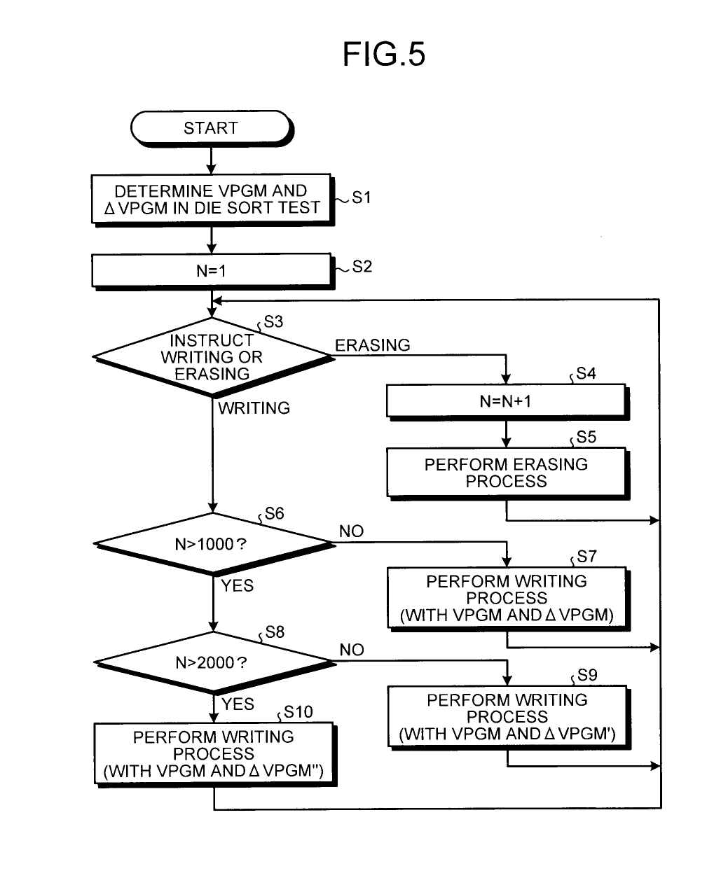

FIG. 5 is a flow chart illustrating a write verifying operation of the non-volatile semiconductor memory device of FIG. 1.

In FIG. 5, in STEP S1, the writing voltage VPGM and the step-up voltage ΔVPGM are determined in a die sort test. Then, in STEP S2, the number of times, N, of erasing is set to 1.

Next, if erasing on a selected block Bi is instructed in STEP S3, in STEP S4, the number of times, N, of erasing for the selected block Bi increases by 1. Next, in STEP S5, an erasing operation on the selected block Bi is performed. In the erasing operation on the block Bi, 0 V is applied to the word lines WL1 to WL1 of the block Bi, and the well potential of the memory cell array 1 is set to an erasing voltage Ve. The erasing voltage Ve can be set to a high voltage, for example, about 20 V. Further, the source line SCE and selection gate lines SGD and SGS of the block Bi can be set to be floated.

In the case where 0 V is applied to the word lines WL1 to WL1 of the block Bi and the well potential of the memory cell array 1 is set to the erasing voltage Ve, a high voltage is applied between the control gate electrodes 16 and wells 11 of the memory cells of the block Bi. Therefore, electrons accumulated in the floating gate electrodes 15 are drawn toward the wells 11. In this way, the erasing operation on the memory cells of the block Bi is performed.

Meanwhile, if writing is instructed in STEP S3, in STEP S6, for example, it is determined whether the number of times, N, of erasing is larger than 1000. If the number of times, N, of erasing is not larger than 1000, in STEP S7, the step-up voltage for stepping up the writing voltage VPGM is set to ΔVPGM, and a writing process is performed.

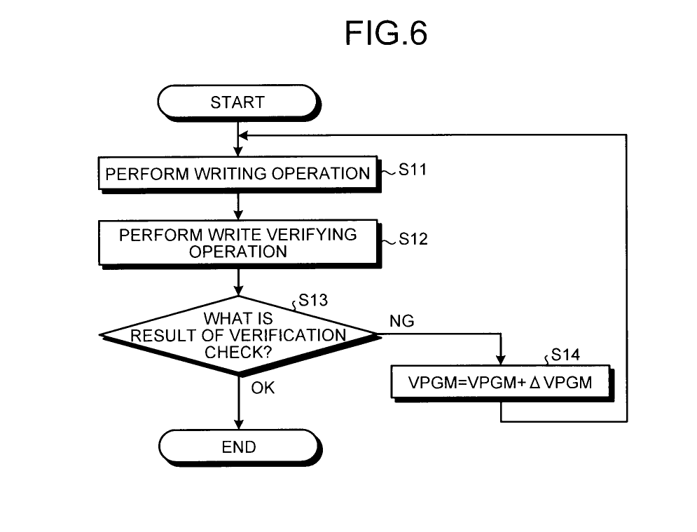

FIG. 6 is a flow chart illustrating the writing process of FIG. 5.

In FIG. 6, in the writing process, in STEP S11, a writing operation is performed. In this writing operation, the writing voltage VPGM is applied to the selected word lines WLk of the block Bi, and 0 V is applied to a selected bit line BLj of the block Bi. Further, to non-selected word lines WL1 to WLk−1 closer to the bit line BLj than the selected word line WLk, a high voltage (for example, 10 V) sufficient to turn on the cell transistors MT1 to MTk−1 is applied. Furthermore, to non-selected word lines WLk+1 to WL1 closer to the source line SCE than the selected word line WLk, a low voltage (for example, 0 V) sufficient to turn off the cell transistors MTk+1 to MT1 is applied.

Also, to the selection gate line SGD, a high voltage sufficient to turn on the selection transistor MS1 is applied, and to the selection gate line SGS, a low voltage sufficient to turn off the selection transistor MS2 is applied.

Then, the voltage of 0 V applied to the bit line BLj is transmitted to the drain of the cell transistor MTk through the cell transistors MT1 to MTk−1 of the NAND cell unit NUj, and at the same time, a high voltage is applied to the control gate electrode 16 of the selected memory cell, such that the potential of the floating gate electrode 15 of the selected cell increases. Therefore, electrons from the drain of the selected cell are injected into the floating gate electrode 15 by a tunneling phenomenon, such that the threshold value of the cell transistor MTk increases. In this way, the writing operation on the selected cell is performed.

If the writing operation on the selected cell of the block Bi is performed, in STEP S12, a write verifying operation is performed to determine whether the threshold value of the selected cell has reached a target threshold value level. At this time, a verifying voltage is applied to the selected word line WLk of the block Bi, and a high voltage (for example, 4.5 V) sufficient to turn on the cell transistors MT1 to MTk−1 and MTk+1 to MT1 is applied to the non-selected word lines WL1 to WLk−1 and WLk+1 to WL1. Further, a high voltage (for example, 4.5 V) sufficient to turn on the selection transistors MS1 and MS2 is applied to the selection gate lines SGD and SGS. Furthermore, a pre-charging voltage is applied to the bit line BLj, and 0 V is applied to the source line SCE.

At this time, if the threshold value of the selected cell has reached the target threshold value level, charge in the bit line BLj is discharged through the NAND cell unit NUj, such that the potential of the bit line BLj becomes a low level. Meanwhile, if the threshold value of the selected cell has not reached the target threshold value level, charge in the bit line BLj is not discharged through the NAND cell unit NUj, such that the potential of the bit line BLj becomes a high level.

Next, in STEP S13, a verification check is performed by determining whether the potential of the bit line BLj is at the low level or at the high level. If the threshold value of the selected cell has reached the target threshold value level, the writing process of STEP S7 of FIG. 5 finishes, and the write verifying operation returns to STEP S3.

Meanwhile, if the threshold value of the selected cell has not reached the target threshold value level, in STEP S14, the writing voltage VPGM increases by the step-up voltage ΔVPGM. Then, the writing voltage VPGM is repeatedly applied until the threshold values of the selected cells reach the target threshold value level while increasing by the step-up voltage ΔVPGM until the verification check is passed.

Meanwhile, in STEP S6 of FIG. 5, in the case where the number of times, N, of erasing is larger than 1000, in STEP S8, for example, it is determined whether the number of times, N, of erasing is larger than 2000. If the number of times, N, of erasing is not larger than 2000, in STEP S9, the step-up voltage for stepping up the writing voltage VPGM is set to ΔVPGM', and a writing process is performed. This writing process is the same as that illustrated in FIG. 6, except that the step-up voltage is changed from ΔVPGM to ΔVPGM'.

Meanwhile, in the case where the number of times, N, of erasing is larger than 2000 in STEP S8 of FIG. 5, in STEP S10, the step-up voltage for stepping up the writing voltage VPGM is set to ΔVPGM″, and a writing process is performed. This writing process is the same as that illustrated in FIG. 6, except that the step-up voltage is changed from ΔVPGM′ to ΔVPGM″. Here, ΔVPGM″ is smaller than ΔVPGM′.

Therefore, if the number of times, N, of erasing increases, the step-up voltage ΔVPGM can be reduced. As a result, even if erasing on memory cells is repeated such that the memory cells are deteriorated, it is possible to suppress the widening of the threshold value distribution of the memory cells, and to make the step-up voltage ΔVPGM before the memory cells are deteriorated larger than that after the memory cells are deteriorated. Further, it is possible to increase the number of times of rewriting while suppressing an increase in writing time.

In the above-mentioned embodiment, the method of reducing the step-up voltage ΔVPGM if the number of times, N, of erasing exceeds 1000 or 2000 has been described. However, it is possible to set an arbitrary value as the number of times, N, of erasing for reducing the step-up voltage ΔVPGM. Further, in the above-mentioned embodiment, the method of reducing the step-up voltage ΔVPGM in two stages has been described. However, it is possible to set an arbitrary value as the number of stages in which the step-up voltage ΔVPGM is reduced.

Furthermore, in the above-mentioned embodiment, the method of changing the step-up voltage ΔVPGM for a writing operation on the basis of the number of times, N, of erasing, has been described. However, on the basis of the number of times, N, of erasing, a bit line voltage for a writing operation may change. In this case, if the number of times, N, of erasing increases, the bit line voltage for the writing operation can increase, such that it is possible to reduce a potential difference between a word line and a channel, and to suppress the widening of the threshold value distribution of the memory cells. For example, in the above-mentioned embodiment, the method of setting 0 V as the bit line voltage for the writing operation has been described. However, if the number of times, N, of erasing exceeds 1000, the bit line voltage may change to 0.5 V, and if the number of times, N, of erasing exceeds 2000, the bit line voltage may change to 0.7 V.

Also, the process of changing the step-up voltage ΔVPGM for the writing operation on the basis of the number of times, N, of erasing, and the process of changing the bit line voltage for the writing operation may be performed at the same time.

In the above-mentioned embodiment, in the case where the verification check of STEP S13 of FIG. 6 is not passed, until the verification check is passed, the writing voltage VPGM is repeatedly applied while increasing by the step-up voltage ΔVPGM. However, the step-up voltage ΔVPGM before the threshold value of the memory cell reaches a verification level set to be below the target threshold value level may be fixed at a value larger than the step-up voltage ΔVPGM after the threshold value of the memory cell reaches the verification level.

Therefore, before the threshold value of the memory cell reaches the verification level set to be below the target threshold value level, it is possible to make the step-up voltage ΔVPGM large, and after the threshold value of the memory cell reaches the verification level, it is possible to make the step-up voltage ΔVPGM small. As a result, it is possible to suppress the widening of the threshold value distribution of the memory cells while suppressing an increase in writing time.

### Second Embodiment

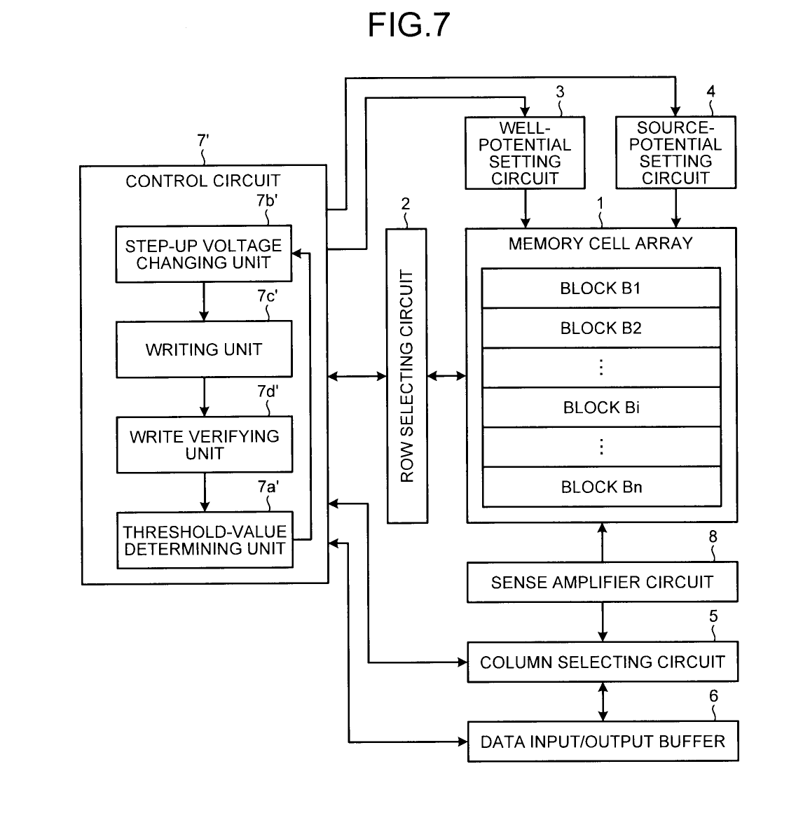

FIG. 7 is a block diagram illustrating a schematic configuration of a non-volatile semiconductor memory device according to a second embodiment.

In FIG. 7, the non-volatile semiconductor memory device includes a control circuit 7′ in place of the control circuit 7 of FIG. 1. The control circuit 7′ includes a threshold-value determining unit 7a′, a step-up voltage changing unit 7b′, a writing unit 7c′, and a write verifying unit 7d′.

The threshold-value determining unit 7a′ can determine the threshold value of the memory cell on the basis of a write verifying operation on the memory cell. The step-up voltage changing unit 7b′ can change the step-up voltage ΔVPGM for stepping up the writing voltage VPGM, on the basis of the threshold value distribution of the memory cells. Specifically, the step-up voltage changing unit 7b′ can reduce the step-up voltage ΔVPGM if the threshold value distribution of the memory cells is wider than a specified value. The writing unit 7c′ can perform a writing operation on the memory cells. Also, the writing unit 7c′ can step up the writing voltage VPGM on the basis of a check result of a verifying operation. The write verifying unit 7d′ can perform a verifying operation with a plurality of verification levels during a writing operation on the memory cells. Examples of the verification levels can include a lower-end verification level corresponding to the lower-end side of the threshold value distribution of the memory cells, and an upper-end verification level corresponding to the upper-end side of the threshold value distribution of the memory cells.

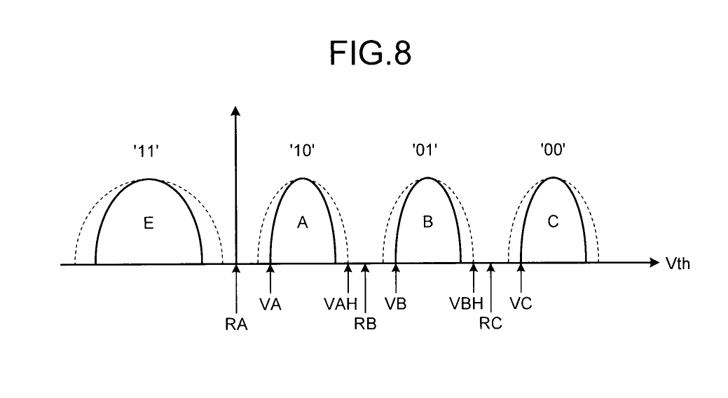

FIG. 8 is a diagram illustrating a threshold voltage distribution of memory cells of the non-volatile semiconductor memory device of FIG. 7 during erasing and writing. In an example of FIG. 8, threshold voltage distributions when four values can be written in the memory cells are illustrated.

In FIG. 8, when data ‘11’ is written in the memory cells (during erasing), the threshold voltages of the memory cells are set in a threshold voltage distribution E. When data ‘10’ is written in the memory cells, the threshold voltages of the memory cells are set in a threshold voltage distribution A. When data ‘01’ is written in the memory cells, the threshold voltages of the memory cells are set in a threshold voltage distribution B. When data ‘00’ is written in the memory cells, the threshold voltages of the memory cells are set in a threshold voltage distribution C.

Then, a reading voltage RA for reading data ‘11’ from the memory cells is set between the threshold voltage distributions E and A. A reading voltage RB for reading data ‘10’ from the memory cells is set between the threshold voltage distributions A and B. A reading voltage RC for reading data ‘01’ from the memory cells is set between the threshold voltage distributions B and C.

When the data ‘10’ is written, in order to perform a verification check, a lower-end verification level VA corresponding to the target threshold value level is set at the lower-end of the threshold voltage distribution A. When the data ‘01’ is written, in order to perform a verification check, a lower-end verification level VB corresponding to the target threshold value level is set at the lower-end of the threshold voltage distribution B. When the data ‘00’ is written, in order to perform a verification check, a lower-end verification level VC corresponding to the target threshold value level is set at the lower-end of the threshold voltage distribution C.

Further, in order to determine the threshold voltage distribution A when the data ‘10’ has been written, an upper-end verification level VAH is set on the upper-end side of the threshold voltage distribution A. In order to determine the threshold voltage distribution B when the data ‘01’ has been written, an upper-end verification level VBH is set on the upper-end side of the threshold voltage distribution B.

Then, if the threshold voltage distribution A when the data ‘10’ has been written exceeds the upper-end verification level VAH, it is possible to determine that the threshold value distribution A is wide, and to reduce the step-up voltage ΔVPGM from the next write cycle.

If the threshold voltage distribution B when the data ‘01’ has been written exceeds the upper-end verification level VBH, it is possible to determine that the threshold value distribution B is wide, and to reduce the step-up voltage ΔVPGM from the next write cycle.

In the case where the threshold voltage distribution A when the data ‘10’ has been written is higher than the upper-end verification level VAH, or the case where the threshold voltage distribution B when the data ‘01’ has been written is higher than the upper-end verification level VBH, from the next write cycle, even in a case where any one of the data ‘10’, ‘01’, and ‘00’ is written, the step-up voltage ΔVPGM may be reduced uniformly.

Alternatively, in the case where the threshold voltage distribution A when the data ‘10’ has been written is higher than the upper-end verification level VAH, and the threshold voltage distribution B when the data ‘01’ has been written is not higher than the upper-end verification level VBH, from the next write cycle, only in a case where the data ‘10’ is written, the step-up voltage ΔVPGM may be reduced.

Otherwise, in the case where the threshold voltage distribution A when the data ‘10’ has been written is not higher than the upper-end verification level VAH, and the threshold voltage distribution B when the data ‘01’ has been written is higher than the upper-end verification level VBH, from the next write cycle, only in a case where the data ‘01’ is written, the step-up voltage ΔVPGM may be reduced.

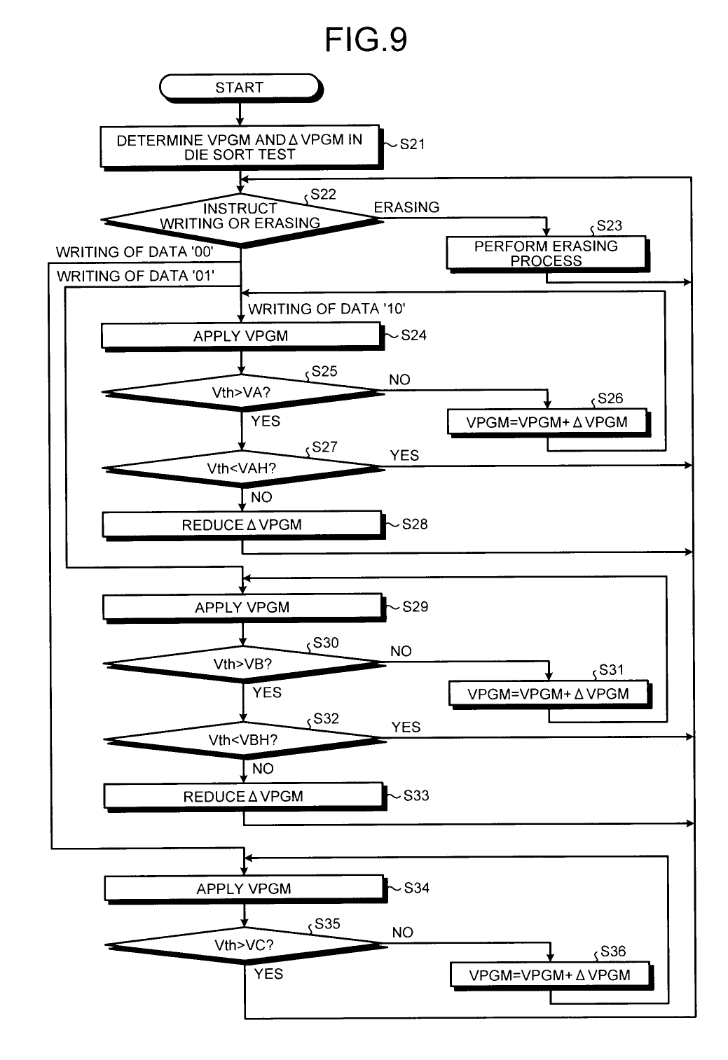

FIG. 9 is a flow chart illustrating a write verifying operation of the non-volatile semiconductor memory device of FIG. 7.

In FIG. 9, in STEP S21, the writing voltage VPGM and the step-up voltage ΔVPGM are determined in a die sort test. Next, if erasing on a selected block Bi is instructed in STEP S22, in STEP S23, an erasing process on the selected block Bi is performed.

Meanwhile, if writing of data ‘10’ is instructed in STEP S22, in STEP S24, the writing voltage VPGM is applied. Then, in STEP S25, it is determined whether the threshold value of the selected cell has reached the lower-end verification level VA. Then, in a case where the threshold value of the selected cell has not reached the lower-end verification level VA, the writing voltage VPGM is applied while being stepped up by the step-up voltage ΔVPGM, in STEP S26, until the threshold value of the selected cell reaches the lower-end verification level VA.

Then, if the threshold value of the selected cell reaches the lower-end verification level VA, in STEP S27, it is determined whether the threshold value of the selected cell is equal to or greater than the upper-end verification level VAH. If the threshold value of the selected cell is equal to or greater than the upper-end verification level VAH, in STEP S28, the step-up voltage ΔVPGM is reduced. Then, the write verifying operation returns to STEP S22.

If writing of data ‘01’ is instructed in STEP S22, in STEP S29, the writing voltage VPGM is applied. Then, in STEP S30, it is determined whether the threshold value of the selected cell has reached the lower-end verification level VB. In a case where the threshold value of the selected cell has not reached the lower-end verification level VB, the writing voltage VPGM is applied while being stepped up by the step-up voltage ΔVPGM, in STEP S31, until the threshold value of the selected cell will reach the lower-end verification level VB.

Then, if the threshold value of the selected cell reaches the lower-end verification level VB, in STEP S32, it is determined whether the threshold value of the selected cell is equal to or greater than the upper-end verification level VBH. If the threshold value of the selected cell is equal to or greater than the upper-end verification level VBH, in STEP S33, the step-up voltage ΔVPGM is reduced. Then, the write verifying operation returns to STEP S22.

If writing of data ‘00’ is instructed in STEP S22, in STEP S34, the writing voltage VPGM is applied. Then, in STEP S35, it is determined whether the threshold value of the selected cell has reached the lower-end verification level VC. In a case where the threshold value of the selected cell has not reached the lower-end verification level VC, the writing voltage VPGM is applied while being stepped up by the step-up voltage ΔVPGM, in STEP S36, until the threshold value of the selected cell reaches the lower-end verification level VC. Then, if the threshold value of the selected cell reaches the lower-end verification level VC, the write verifying operation returns to STEP S22.

In this way, it is possible to reduce the step-up voltage ΔVPGM in accordance with the actual widening of the threshold value distribution of the memory cells. Therefore, even if the threshold value distribution of the memory cells actually widens, it is possible to suppress the widening of the threshold value distribution of the memory cells, and to make the step-up voltage ΔVPGM before the threshold value distribution of the memory cells widens higher than that after the threshold value distribution of the memory cells widens. Further, it is possible to increase the number of times of rewriting while suppressing an increase in writing time.

In the above-mentioned embodiment, the method of changing the step-up voltage ΔVPGM for a writing operation on the basis of the widening of the threshold value distribution of the memory cells has been described. However, on the basis of the widening of the threshold value distribution of the memory cells, the bit line voltage for a writing operation may change. Further, the process of changing the step-up voltage ΔVPGM for a writing operation on the basis of the widening of the threshold value distribution of the memory cells, and the process of changing the bit line voltage for the writing operation may be performed at the same time.

In the above-mentioned embodiment, in the case where writing of the data ‘10’ has been instructed, if the threshold value of the selected cell has not reached the lower-end verification level VA, the writing voltage VPGM is repeatedly applied while being stepped up by the step-up voltage ΔVPGM, until the threshold value of the selected cell reaches the lower-end verification level VA. However, the step-up voltage ΔVPGM before the threshold value of the memory cell reaches a verification level set to be below the target threshold value level may be fixed at a value larger than the step-up voltage ΔVPGM after the threshold value of the memory cell reaches the verification level. This is applicable even to the case where writing of data ‘01’ or ‘00’ is instructed.

### Third Embodiment

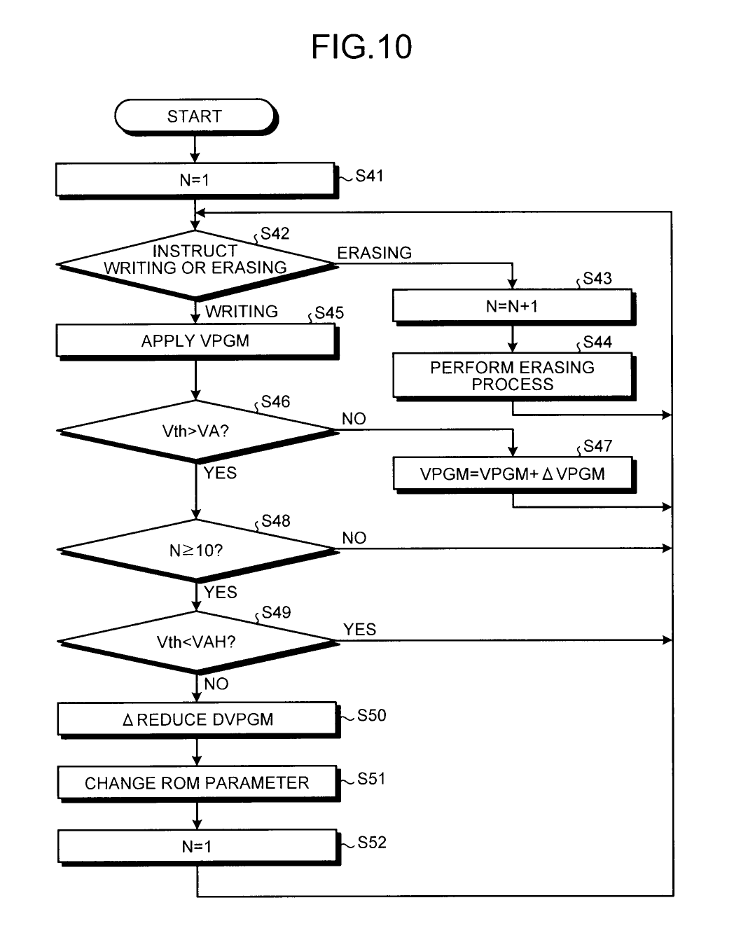

FIG. 10 is a flow chart illustrating a write verifying operation of a non-volatile semiconductor memory device according to a third embodiment. In an example of FIG. 10, a case where data ‘10’ is written is illustrated, but a case where data ‘01’ or ‘00’ is written is not illustrated.

In FIG. 10, in STEP S41, the number of times, N, of erasing is set to 1. Next, if erasing on the selected block Bi is instructed in STEP S42, in STEP S43, the number of times, N, of erasing on the selected block Bi increases by 1. Then, in STEP S44, an erasing process on the selected block Bi is performed.

Meanwhile, if writing of data ‘10’ is instructed in STEP S42, in STEP S45, the writing voltage VPGM is applied. Then, in STEP S46, it is determined whether the threshold value of the selected cell has reached the lower-end verification level VA. If the threshold value of the selected cell has not reached the lower-end verification level VA, the writing voltage VPGM is applied while being stepped up by the step-up voltage ΔVPGM in STEP S47, until the threshold value of the selected cell reaches the lower-end verification level VA.

Then, if the threshold value of the selected cell reaches the lower-end verification level VA, in STEP S48, it is determined whether the number of times, N, of erasing is equal to or larger than 10. If the number of times, N, of erasing is smaller than 10, the write verifying operation returns to STEP S42. Meanwhile, if the number of times, N, of erasing is equal to or larger than 10, in STEP S49, it is determined whether the threshold value of the selected cell is equal to or greater than the upper-end verification level VAH. If the threshold value of the selected cell is equal to or greater than the upper-end verification level VAH, in STEP S50, the step-up voltage ΔVPGM is reduced. Next, in STEP S51, a ROM parameter changes in accordance with the change in the step-up voltage ΔVPGM, and in STEP S52, the number of times, N, of erasing is set to 1. Then, the write verifying operation returns to STEP S42.

In this way, it is possible to reduce the step-up voltage ΔVPGM in accordance with the actual widening of the threshold value distribution of the memory cells, and to determine whether the threshold value of the selected cell is equal to or greater than the upper-end verification level VAH whenever the erasing operation is performed ten times. Therefore, it is possible to suppress the widening of the threshold value distribution of the memory cells while suppressing unnecessary stress on the memory cells. Further, it is possible to make the step-up voltage ΔVPGM before the threshold value distribution of the memory cells widens higher than that after the threshold value distribution of the memory cells widens. Furthermore, it is possible to increase the number of times of rewriting while suppressing an increase in writing time.

In the above-mentioned embodiment, the method of determining whether the threshold value of the selected cell is equal to or greater than the upper-end verification level VAH when the number of times, N, of erasing is equal to or larger than 10 has been described. However, it is possible to set an arbitrary value as the number of times, N, of erasing for determining whether the threshold value of the selected cell is equal to or greater than the upper-end verification level VAH.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor memory device comprising:
a memory cell array that includes a plurality of memory cells for each block;
a write verifying unit that performs a verifying operation with a plurality of verification levels during a writing operation on the memory cells;
a writing unit that performs the writing operation on the memory cells while stepping up a writing voltage based on a check result of the verifying operation;
a threshold-value determining unit that determines threshold values of the memory cells based on a write verifying operation on the memory cells; and
a step-up voltage changing unit that changes a step-up voltage for stepping up the writing voltage, based on the threshold values of the memory cells.

2. The non-volatile semiconductor memory device according to claim 1,
wherein the threshold-value determining unit determines whether a threshold value distribution of the memory cells exceeds an upper-end verification level, and
if the threshold value distribution of the memory cells exceeds the upper-end verification level, the step-up voltage changing unit reduces the step-up voltage.

3. The non-volatile semiconductor memory device according to claim 2,
wherein, after the writing voltage is applied to the memory cells, it is determined whether the threshold values of the memory cells have reached a lower-end verification level, and if the threshold values of the memory cells have not reached the lower-end verification level, the writing voltage is applied while being stepped up by the step-up voltage, until the threshold values of the memory cells reach the lower-end verification level, and
if the threshold values of the memory cells reach the lower-end verification level, it is determined whether the threshold values of the memory cells are equal to or greater than the upper-end verification level, and if the threshold values of the memory cells are equal to or greater than the upper-end verification level, the step-up voltage is reduced.

4. The non-volatile semiconductor memory device according to claim 3,
wherein if the threshold values of the memory cells reach the lower-end verification level, it is determined whether the number of times of erasing on the memory cells is equal to or greater than a specified value, and if the number of times of erasing is less than the specified value, the process of determining whether the threshold values of the memory cells are equal to or greater than the upper-end verification level is skipped, and if the number of times of erasing on the memory cells is equal to or greater than the specified value, it is determined whether the threshold values of the memory cells are equal to or greater than the upper-end verification level.

5. The non-volatile semiconductor memory device according to claim 1,
wherein the threshold-value determining unit determines a threshold value distribution of the memory cells when the number of times of erasing on the memory cells is equal to or greater than a specified value.

6. The non-volatile semiconductor memory device according to claim 1,
wherein before the threshold values reach a verification level set to be below a target threshold value level, the step-up voltage changing unit fixes the step-up voltage at a value larger than that after the threshold values reach the verification level.

7. The non-volatile semiconductor memory device according to claim 1,
wherein the block includes a plurality of NAND cell units arranged in a row direction.

8. The non-volatile semiconductor memory device according to claim 7,
wherein each of the NAND cell units includes a NAND string that is configured to include a plurality of cell transistors connected in series,
a first selection transistor that is connected to one end of the NAND string, and
a second selection transistor that is connected to the other end of the NAND string.

9. The non-volatile semiconductor memory device according to claim 8,
wherein control gate electrodes of the cell transistors are connected to word lines, the one end of the NAND string is connected to a bit line through the first selection transistor, and the other end of the NAND string is connected to a source line through the second selection transistor.

10. The non-volatile semiconductor memory device according to claim 9,
wherein, during the writing operation, a bit line voltage changes based on widening of a threshold value distribution of the memory cells.

11. The non-volatile semiconductor memory device according to claim 9, further comprising:
a row selecting circuit that selects memory cells in the row direction of the memory cell array during reading, writing, or erasing on the memory cells;
a well-potential setting circuit that sets a well potential of the memory cell array during the reading, writing, or erasing on the memory cells;
a source-potential setting circuit that sets a source potential of the memory cell array during the reading, writing, or erasing on the memory cells;
a column selecting circuit that selects memory cells in a column direction of the memory cell array during the reading, writing, or erasing on the memory cells; and
a sense amplifier circuit that determines data read from the memory cells for each column.

12. The non-volatile semiconductor memory device according to claim 1,
wherein, in a case where the number of times of erasing on the memory cells is equal to or less than a specified value, the step-up voltage is set to a first value, and the writing voltage is repeatedly applied while increasing by the first value, until a verification check is passed, and
in a case where the number of times of erasing exceeds the specified value, the step-up voltage is set to a second value smaller than the first value, and the writing voltage is repeatedly applied while increasing by the second value, until the verification check is passed.

13. A non-volatile semiconductor memory device comprising:
a memory cell array that includes a plurality of memory cells for each block;
a write verifying unit that performs a verifying operation during a writing operation on the memory cells;
a writing unit that performs the writing operation on the memory cells while stepping up a writing voltage based on a check result of the verifying operation;
a number-of-times-of-erasing counting unit that counts the number of times of erasing on the memory cells for each block; and
a step-up voltage changing unit that changes a step-up voltage for stepping up the writing voltage, based on the number of times of erasing.

14. The non-volatile semiconductor memory device according to claim 13,
wherein before the threshold values reach a verification level set to be below a target threshold value level, the step-up voltage changing unit fixes the step-up voltage at a value larger than that after the threshold values reach the verification level.

15. The non-volatile semiconductor memory device according to claim 13,
wherein the block includes a plurality of NAND cell units arranged in a row direction.

16. The non-volatile semiconductor memory device according to claim 15,
wherein each of the NAND cell units includes a NAND string that is configured to include a plurality of cell transistors connected in series,
a first selection transistor that is connected to one end of the NAND string, and
a second selection transistor that is connected to the other end of the NAND string.

17. The non-volatile semiconductor memory device according to claim 16,
wherein control gate electrodes of the cell transistors are connected to word lines, the one end of the NAND string is connected to a bit line through the first selection transistor, and the other end of the NAND string is connected to a source line through the second selection transistor.

18. The non-volatile semiconductor memory device according to claim 17,
wherein a bit line voltage during the writing operation is changed based on the number of times of erasing on the memory cells.

19. The non-volatile semiconductor memory device according to claim 17, further comprising:
a row selecting circuit that selects memory cells in the row direction of the memory cell array during reading, writing, or erasing on the memory cells;
a well-potential setting circuit that sets a well potential of the memory cell array during the reading, writing, or erasing on the memory cells;
a source-potential setting circuit that sets a source potential of the memory cell array during the reading, writing, or erasing on the memory cells;
a column selecting circuit that selects memory cells in a column direction of the memory cell array during the reading, writing, or erasing on the memory cells; and
a sense amplifier circuit that determines data read from the memory cells for each column.

20. The non-volatile semiconductor memory device according to claim 13,
wherein, in a case where the number of times of erasing on the memory cells is equal to or less than a specified value, the step-up voltage is set to a first value, and the writing voltage is repeatedly applied while increasing by the first value, until a verification check is passed, and
in a case where the number of times of erasing exceeds the specified value, the step-up voltage is set to a second value smaller than the first value, and the writing voltage is repeatedly applied while increasing by the second value, until the verification check is passed.
